(19) United States
(12) Patent Application Publication
(10) Pub. No.: US 2005/0263822 A1
(43) Pub. Date: Dec. 1, 2005

(54) Semiconductor device and manufacturing method thereof

(75) Inventor: Tetsuro Asano, Gunma (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/138,649

(22) Filed: May 27, 2005

(30) Foreign Application Priority Data
May 28, 2004 (JP) 2004-158563

(51) Int. Cl. H01L 23/62; H01L 21/20

(52) U.S. Cl. 257/357; 438/381

(57) ABSTRACT

In the case where a HEMT and a resistor element are monolithically integrated, the resistor element has a low sheet resistance value since the resistor element includes a cap layer. If a resistor having a high resistance value is formed, it is required to extend the resistor for a long distance within a chip. As a result, a chip area is increased. A recessed part is provided by removing a cap layer in a predetermined shape, and resistor element electrodes are connected to both ends of the recessed part. A resistor layer is only a channel layer, and a sheet resistance value is high. Thus, a high resistance value can be obtained with a short distance. Since a sufficiently high resistance value can be obtained without extending a resistor for a long distance within a chip, a chip size can be reduced.

### BACKGROUND OF THE INVENTION

1. Field of the Invention

The present invention relates to a semiconductor device and a manufacturing method thereof, and more particularly relates to a semiconductor device which suppresses an increase in a chip occupation area, and a manufacturing method thereof.

2. Description of the Related Art

In recent years, there has been a strong demand for miniaturization and low power consumption of terminal devices in a mobile communication system such as a mobile telephone. Thus, also as to various monolithic microwave integrated circuits (MMIC) which are used for transmitting/receiving RF (radio frequency) circuits, there has been an increasing demand for miniaturization and low power consumption.

Among those devices, a device having a heterojunction, which is typified by a HEMT (High Electron Mobility Transistor), is excellent in efficiency, gains, and distortion characteristics, compared with a GaAs MESFET (Metal Semiconductor FET) and a GaAs JFET (Junction FET). Thus, the device described above is becoming the mainstream device of the MMIC. Therefore, there is a strong demand for miniaturization and low power consumption of the device having the heterojunction. Relevant technologies are described in, for example, Japanese Patent Application Publication No. Hei 11-136111.

### SUMMARY OF THE INVENTION

The invention provides a semiconductor device that includes a semiconductor substrate, a multi-layer stack formed on the semiconductor substrate, the stack comprising a buffer layer formed on the semiconductor substrate, a first electron supply layer formed on the buffer layer, a channel layer formed on the first electron supply layer, a second electron supply layer formed on the channel layer, a barrier layer formed on the second electron supply layer, and a cap layer formed on the barrier layer, an active device element formed on the stack, and a resistor element connected with the active device element, the resistor element comprising a first resister element electrode and a second resistor element electrode that are formed on the cap layer, wherein the cap layer is removed along a path between the first and second resistor element electrodes.

The invention also provides a method of manufacturing a semiconductor device. The method includes providing a semiconductor substrate having a multi-layer stack formed thereon, the stack comprising a buffer layer formed on the semiconductor substrate, a first electron supply layer formed on the buffer layer, a channel layer formed on the first electron supply layer, a second electron supply layer formed on the channel layer, a barrier layer formed on the second electron supply layer, and a cap layer formed on the barrier layer, removing a first portion of the cap layer to form a recess, forming a first resistor element electrode on the cap layer and adjacent one end of the recess, forming a second resister element electrode on the cap layer and adjacent other end of the recess, and filling the recess with an insulating film.

### BRIEF DESCRIPTION OF THE DRAWINGS

FIG. 1 is a schematic circuit diagram showing a first embodiment of the present invention.

FIG. 2 is a plan view showing the first embodiment of the present invention.

FIGS. 3A and 3B are cross-sectional views showing the first embodiment of the present invention.

FIG. 4 is a cross-sectional view showing the first embodiment of the present invention.

FIG. 5 is a cross-sectional view showing the first embodiment of the present invention.

FIG. 6 is a cross-sectional view showing the first embodiment of the present invention.

FIG. 7 is a cross-sectional view showing the first embodiment of the present invention.

FIGS. 8A and 8B are cross-sectional views showing the first embodiment of the present invention.

FIGS. 9A and 9B are cross-sectional views showing the first embodiment of the present invention.

FIGS. 10A and 10B are cross-sectional views showing the first embodiment of the present invention.

FIG. 11 is a cross-sectional view showing the first embodiment of the present invention.

FIG. 12 is a cross-sectional view showing a second embodiment of the present invention.

FIGS. 13A to 13C are cross-sectional views showing the second embodiment of the present invention.

FIG. 14 is a cross-sectional view showing a third embodiment of the present invention.

FIGS. 15A to 15C are cross-sectional views showing the third embodiment of the present invention.

FIG. 16 is a plan view showing a device forming the basis of the device of the first embodiment.

FIGS. 17A and 17B are cross-sectional views showing the device of FIG. 16.

### DESCRIPTION OF THE EMBODIMENTS

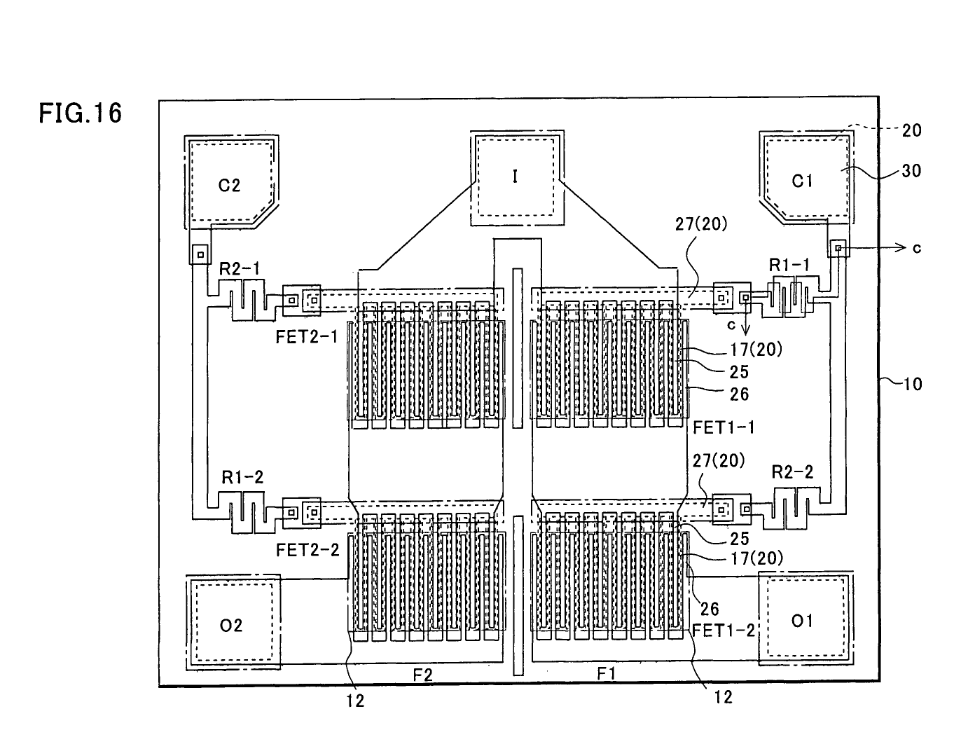

FIG. 16 is a plan view showing a semiconductor device that forms a basis of one of the embodiments of the invention. HEMTs and resistor elements are monolithically integrated in this device.

Here, as an example, a switch circuit device called SPDT (Single Pole Double Throw) will be described, in which multiple stages of HEMTs (FETs) are serially connected for high-power use.

On a GaAs substrate, two FET groups F1 and F2 which perform switching are disposed. The FET group F1 is, for example, a group in which a FET1-1 and a FET1-2 are serially connected. The FET group F2 is a group in which a FET2-1 and a FET2-2 are serially connected. Resistors R1-1, R1-2, R2-1, and R2-2 are connected to four gate electrodes included in the respective FET groups, respectively. Moreover, in a periphery of the substrate, electrode pads I, O1, O2, C1, and C2 are provided, which correspond to a common input terminal IN, output terminals OUT1 and OUT2, and control terminals Ctl-1 and Ctl-2. Note that a metal layer of a second layer indicated by a dotted line is a gate metal layer (Ti/Pt/Au) 20 which is formed simultaneously with formation of the gate electrodes of the respective FETs. In addition, a metal layer of a third layer indicated by a solid line is a pad metal layer (Ti/Pt/Au) 30 which connects respective elements and forms the pads. An ohmic metal layer (AuGe/Ni/Au) of a first metal layer, which is ohmically connected to the substrate, forms source electrodes and drain electrodes of the respective FETs, and extracts electrodes at both ends of the respective resistors. The ohmic metal layer is not shown in FIG. 16 because the layer is overlapped by the pad metal layer.

The FET groups F1 and F2 are symmetrically arranged on either side of a center line of a chip. Since the both groups have the same configuration, the FET group F1 will be described below. In the FET1-1, 8 comb-teeth-shaped pad metal layers 30 of the third metal layer, which are extended from an upper side, are source electrodes 25 (or drain electrodes) which are connected to the common input terminal pad I, and source electrodes (or drain electrodes) which are formed of the ohmic metal layer of the first metal layer, are disposed therebelow. Moreover, 9 comb-teeth-shaped pad metal layers 30 of the third metal layer, which are extended from a lower side, are drain electrodes 26 (or source electrodes) of the FET1-1, and drain electrodes (or source electrodes) which are formed of the ohmic metal layer of the first metal layer are disposed therebelow. The both electrodes are arranged in a shape of engaged comb teeth. Between the electrodes, 16 comb-teeth-shaped gate electrodes 17 are disposed, which are formed of the gate metal layer 20 of the second metal layer.

Below the source electrodes 25, the drain electrodes 26, and the gate electrodes 17, an operation region 12 that is an impurity region is provided as indicated by a dashed-dotted line.

In the FET1-2, 8 comb-teeth-shaped pad metal layers 30 of the third metal layer, which are extended from an upper side, are the source electrodes 25 (or drain electrodes), and source electrodes (or drain electrodes) which are formed of the ohmic metal layer of the first metal layer are disposed therebelow. Moreover, 9 comb-teeth-shaped pad metal layers 30 of the third metal layer, which are extended from a lower side, are the drain electrodes 26 (or source electrodes) which are connected to the output terminal pad O1, and drain electrodes (or source electrodes) which are formed of the ohmic metal layer of the first metal layer are disposed therebelow. The both electrodes are arranged in a shape of engaged comb teeth. Between the electrodes, the 16 comb-teeth-shaped gate electrodes 17 are disposed, which are formed of the gate metal layer 20 of the second metal layer.

Outside the operation region 12, the gate electrodes 17 are bundled by use of a wiring formed of the gate metal layer 20 (hereinafter referred to as a gate wiring), and are connected to the control terminal pad C1 through the resistors R1-1 and R1-2 formed of impurity regions.

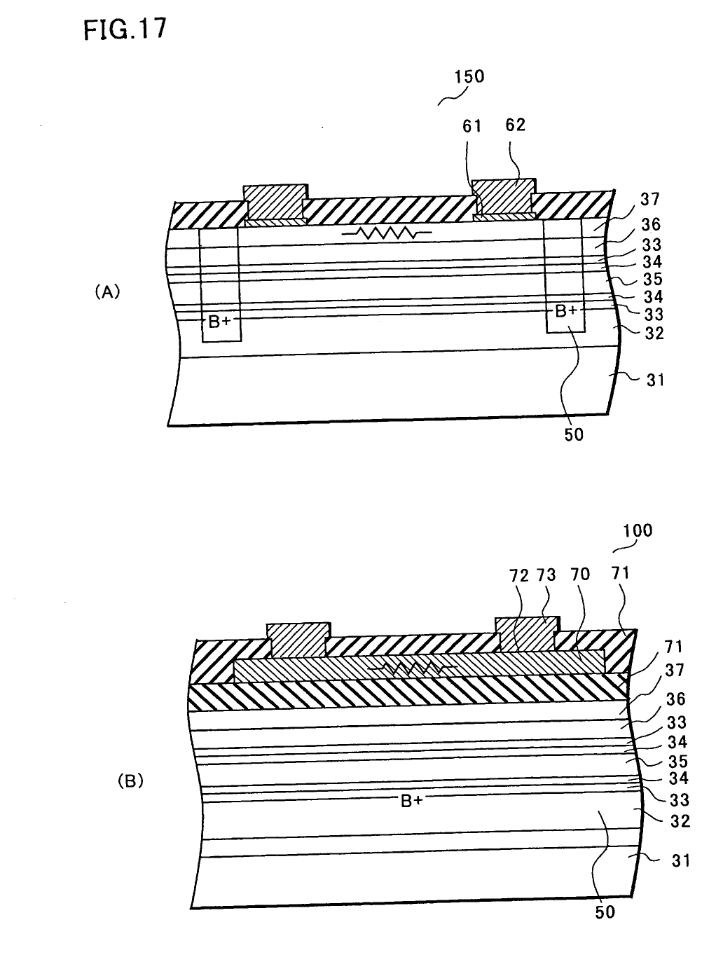

FIGS. 17A and 17B are cross-sectional views along the line c-c in FIG. 16. A HEMT substrate is formed by sequentially growing, on a semi-insulating GaAs substrate 31, an undoped buffer layer 32, an n+ type AlGaAs layer 33 to be an electron supply layer, an undoped InGaAs layer 35 to be a channel (electron transit) layer, and an n+ type AlGaAs layer 33 to be an electron supply layer. Moreover, between the respective electron supply layers 33 and the channel layer 35, spacer layers 34 are disposed.

An undoped AlGaAs layer 36 that is a barrier layer is grown on the electron supply layer 33 to secure a predetermined breakdown voltage and a pinch-off voltage. Moreover, an n+ type GaAs layer 37 to be a cap layer is grown as an uppermost layer. The metal layers such as the source electrodes, the drain electrodes, and the extracting electrodes of the resistors are connected to the cap layer 37. Thus, ohmic characteristics are improved.

Here, in a GaAs MESFET and the like, impurity regions are formed in such a manner that ions of impurities are implanted, and high-temperature annealing is performed at about 800° C. to 900° C. to activate the implanted impurity ions so as to have a conductivity. However, in the device having the heterojunction, such as the HEMT, unlike the GaAs MESFET and the like, a substrate in which a plurality of thin operating layers (the electron supply layers and the channel layer) are subjected to epitaxial growth on the semi-insulating substrate is used as described above. Thus, since the high-temperature annealing destroys a crystal structure of an expitaxial layer, the impurity regions cannot be formed by use of the method described above.

Therefore, in the HEMT, the impurity regions are formed by isolating the substrate by use of an insulating region 50.

Specifically, as shown in FIG. 17A, a resistor element 150, which is monolithically formed on the same substrate as that of the HEMT, is isolated by use of the insulating region 50, and is formed into a pattern (a width and a length) having a predetermined resistance value (see FIG. 16). The resistor element 150 has resistor element electrodes 61 and 62 connected on its both ends. In this case, since the cap layer 37 has the highest impurity concentration and a large layer thickness, the cap layer 37 becomes a main current path of this resistor element 150.

Alternatively, as shown in FIG. 17B, an insulating film 71 such as a insulating film is provided on the entire surface of the cap layer 37, and a metal layer 70 such as NiCr is deposited thereon. Thereafter, patterning is performed to obtain a predetermined resistance value, and a resistor element electrode 73 is provided. Thus, the resistor element 150 is formed.

However, in the case of FIG. 17A, the cap layer 37 to be an actual resistor layer has a low sheet resistance. Therefore, in order to form a control resistor (10 KΩ) of the switch circuit device shown in FIG. 16, it is required either to sufficiently reduce a width thereof or to sufficiently secure a length thereof. Practically, since miniaturization of the pattern has its limits, it is required to secure a desired resistance value by controlling the length. Therefore, as the resistor is increased in size, the resistor is not fitted into a gap between the pads or the elements on the chip. Accordingly, there arises a need to prepare a special space only for disposing the resistor. Thus, there is a problem that a chip area is increased.

Meanwhile, in the case of FIG. 17B, since the resistor layer is the NiCr layer 70, the sheet resistance is high. However, there are required steps of depositing the NiCr layer 70, performing lift-off, forming the insulating film 71 on the NiCr layer 70, and forming a contact 72. These steps need to be performed separately from the steps of manufacturing the HEMT. Thus, there is a problem that monolithic integration of the resistor element 150 increases the number of steps.

The following embodiments of the invention are directed to solving these problems.

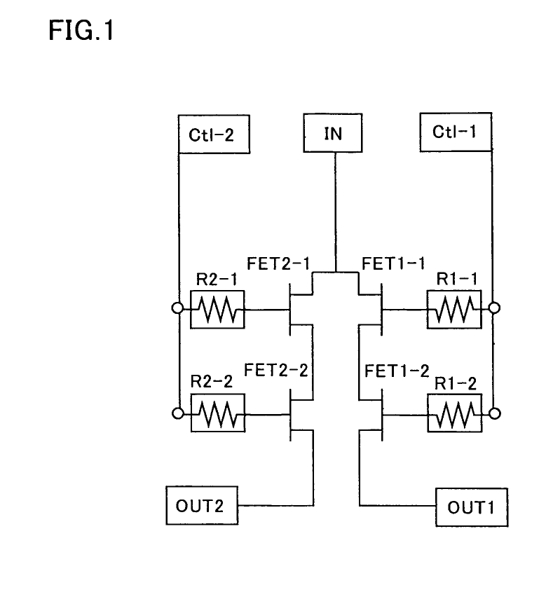

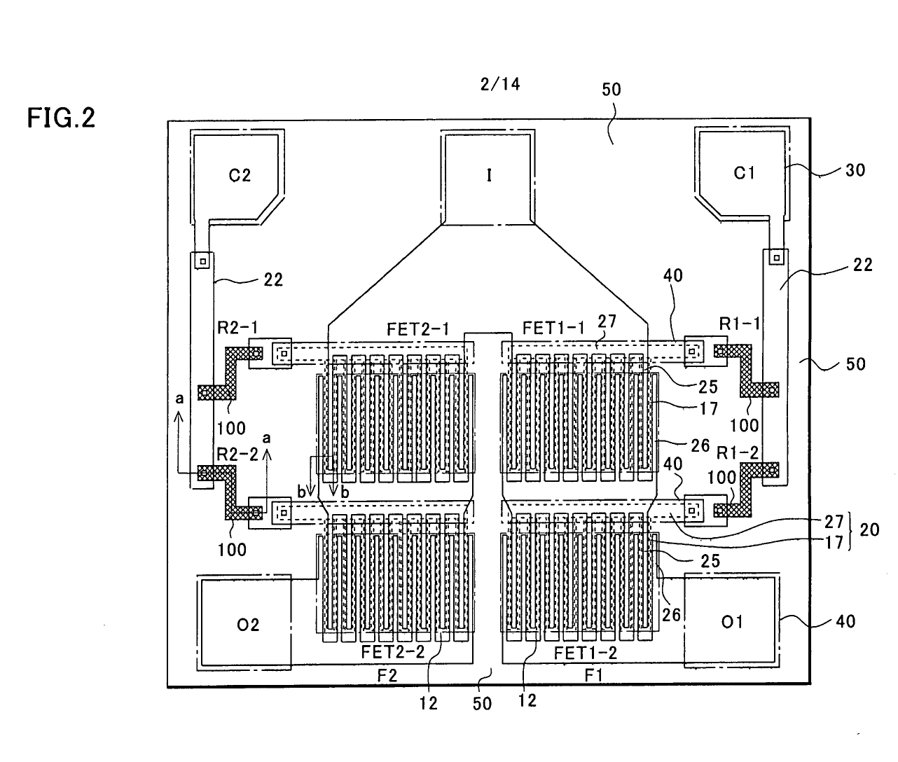

First, with reference to FIGS. 1 and 2, a first embodiment of the present invention will be described.

FIG. 1 shows a semiconductor device in which HEMTs and resistor elements are monolithically integrated. Here, as an example, a switch circuit device called SPDT (Single Pole Double Throw) will be described, in which multiple stages of HEMTs (FETs) are serially connected for high-power use.

Control signals applied to first and second control terminals Ctl-1 and Ctl-2 are complementary signals. A FET group to which a H-level signal is applied is turned on, and an input high-frequency signal entering a common input terminal IN is transmitted to any one of output terminals. For direct-current potentials of the control terminals Ctl-1 and Ctl-2 to be subjected to alternating-current grounding, resistors are provided for the purpose of preventing leakage of high-frequency signals through gate electrodes.

Gate electrodes of a FET1-1 and a FET1-2 are connected to the first control terminal Ctl-1 through resistors R1-1 and R1-2, respectively. Gate electrodes of a FET2-1 and a FET2-2 are connected to the second control terminal Ctl-2 through resistors R2-1 and R2-2, respectively.

When a high-frequency signal is transmitted from the common input terminal IN to an first output terminal OUT1, a bias signal of 3V, for example, is applied to the first control terminal Ctl-1, and a bias signal of 0V is applied to the second control terminal Ctl-2. On the other hand, when a high-frequency signal is transmitted from the common input terminal IN to an second output terminal OUT2, a bias signal of 3V is applied to the second control terminal Ctl-2, and a bias signal of 0V is applied to the first control terminal Ctl-1.

FIG. 2 is a plan view showing integration of the switch circuit device of FIG. 1 in one chip. In the switch circuit device, two FET groups F1 and F2 which perform switching are disposed on a substrate. The FET group F1 is, for example, a group in which the FET1-1 and the FET1-2 are serially connected. The FET group F2 is a group in which the FET2-1 and the FET2-2 are serially connected. Resistor elements R1-1, R1-2, R2-1, and R2-2, which are formed of impurity regions, are connected to four gate electrodes included in the respective FET groups, respectively. Moreover, in a periphery of the substrate, electrode pads I, O1, O2, C1, and C2 are provided, which correspond to the common input terminal IN, the first and second output terminals OUT1 and OUT2, and the first and second control terminals Ctl-1 and Ctl-2, respectively. Note that a metal layer of a second layer indicated by a dotted line is a gate metal layer (for example, Pt/Mo) 20 which is formed simultaneously with formation of the gate electrodes of the respective FETs. In addition, a metal layer of a third layer indicated by a solid line is a pad metal layer (Ti/Pt/Au) 30 which connects respective elements and forms the pads. An ohmic metal layer (AuGe/Ni/Au) of a first metal layer, which is ohmically connected to the substrate, forms source electrodes and drain electrodes of the respective FETs, and extracting electrodes at both ends of the respective resistor elements R1-1,R1-2,R2-1 and R2-2. The ohmic metal layer is not shown in FIG. 2 because the layer is overlapped by the pad metal layer.

The FET groups F1 and F2 are symmetrically arranged on either side of a center line of the chip. Since the both groups have the same configuration, the FET group F1 will be described below. In the FET1-1, 8 comb-teeth-shaped pad metal layers 30 of the third metal layer, which are extended from an upper side, are source electrodes 25 (or drain electrodes 26) which are connected to the common input terminal pad I, and source electrodes (or drain electrodes) which are formed of the ohmic metal layer of the first metal layer, are disposed therebelow. Moreover, 9 comb-teeth-shaped pad metal layers 30 of the third metal layer, which are extended from a lower side, are the drain electrodes 26 (or the source electrodes 25) of the FET1-1, and the drain electrodes (or the source electrodes) which are formed of the ohmic metal layer of the first metal layer are disposed therebelow. The both electrodes 25 and 26 are arranged in a shape of engaged comb teeth. Between the electrodes, 16 comb-teeth-shaped gate electrodes 17 are disposed, which are formed of the gate metal layer 20 of the second metal layer.

In the FET1-2, 8 comb-teeth-shaped pad metal layers 30 of the third metal layer, which are extended from an upper side, are the source electrodes 25 (or the drain electrodes 26), and the source electrodes (or the drain electrodes) which are formed of the ohmic metal layer of the first metal layer are disposed therebelow. Moreover, 9 comb-teeth-shaped pad metal layers 30 of the third metal layer, which are extended from a lower side, are the drain electrodes 26 (or the source electrodes 25) which are connected to the first output terminal pad O1, and the drain electrodes (or the source electrodes) which are formed of the ohmic metal layer of the first metal layer are disposed therebelow. The both electrodes 25 and 26 are arranged in a shape of engaged comb teeth. Between the electrodes, 16 comb-teeth-shaped gate electrodes 17 are disposed, which are formed of the gate metal layer 20 of the second metal layer.

As described above, operation regions 12 of the switch circuit device are impurity regions which are formed by isolating the region indicated by the dashed-dotted line by use of insulating region 50. The source electrodes 25 and the drain electrodes 26 are connected to a source region and a drain region of each of the operation regions 12. In addition, the gate electrodes 17 form a Schottky junction with a part of the operation region 12.

Moreover, outside the operation regions 12, the gate electrodes 17 are bundled by use of gate wirings 27, and are connected to resistor element electrodes on one end of resistor elements 100(R1-1 and R1-2). The resistor element electrodes on the other end are connected to wirings 22 formed of the pad metal layer 30 provided on the insulating region 50, and are connected to the first control terminal pad C1.

Below and around the respective pads (I,O1,O2,C1 and C2) and the gate wirings 27, peripheral impurity regions 40 for isolation improvement are formed by being isolated by the insulating regions 50.

Although the resistor element 100 is also a region formed by being isolated by the insulating region 50, a part of a cap layer on a surface of the resistor element 100 is removed by etching.

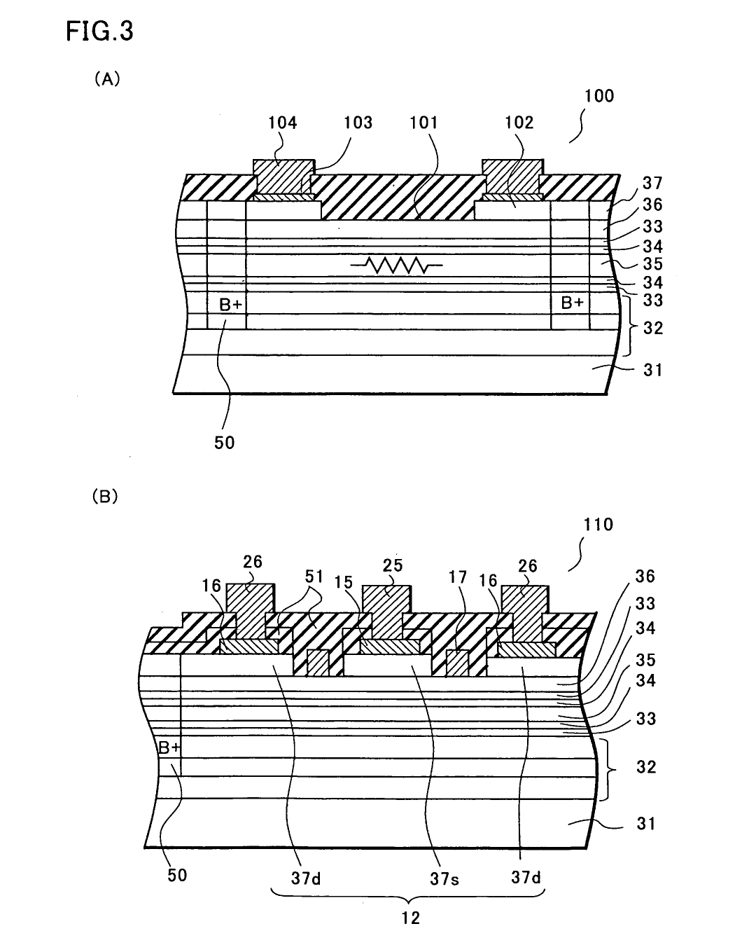

FIGS. 3A and 3B are partial cross-sectional views of FIG. 2. FIG. 3A is a cross-sectional view along the line a-a in FIG. 2, and FIG. 3B is a cross-sectional view along the line b-b in FIG. 2.

As shown in FIG. 3A, the substrate is formed by sequentially growing, on a semi-insulating GaAs substrate 31, an undoped buffer layer 32, an n+ type AlGaAs layer 33 to be an electron supply layer, an undoped InGaAs layer 35 to be a channel (electron transit) layer, and an n+ type AlGaAs layer 33 to be an electron supply layer. Moreover, between the respective electron supply layers 33 and the channel layer 35, spacer layers 34 are disposed.

The buffer layer 32 is a high-resistance layer having no impurities doped therein, and a thickness thereof is about several thousand Å. An undoped AlGaAs layer to be a barrier layer 36 is grown on the electron supply layer 33 to secure a predetermined breakdown voltage and a pinch-off voltage. Moreover, an n+ type GaAs layer 37 to be a cap layer is grown as an uppermost layer.

The electron supply layers 33, the barrier layer 36, and the spacer layers 34 are formed by use of a material having a band gap larger than that of the channel layer 35. Moreover, in the electron supply layers 33, about 2 to 4×10¹⁸ cm⁻³ of n-type impurities (for example, Si) are doped.

With such a structure, electrons generated from donor impurities in the n+ type AlGaAs layers, which are the electron supply layers 33, move toward the channel layer 35, and a channel to be a current path is formed. As a result, the electrons and donor ions are spatially separated on a heterojunction interface. The electrons move through the channel layer 35, in which no donor ions exist. Thus, the electrons are hardly affected by Coulomb scattering, and a high electron mobility can be achieved.

The resistor element 100 of this embodiment is formed by isolating the substrate by use of the insulating region 50, and has a recessed part 101 which is formed by etching a part of the cap layer 37. The cap layer 37 to be contact parts 102 are left at both ends of the recessed part 101, and resistor element electrodes 103 and 104 are connected to each of the contact parts 102. The resistor element electrode 103 is formed of the same ohmic metal layer 10 as that of the source and drain electrodes in the first metal layer of the HEMT. The resistor element electrode 104 is formed of the same pad metal layer 30 as that of the source and drain electrodes 25 and 26 in the third metal layer. In addition, the barrier layer 36 is exposed in a bottom of the recessed part 101.

As described above, by providing the recessed part 101 in which the barrier layer 36 is exposed, the resistor element electrodes 103 and 104, the contact parts 102, and the channel layer 35 form a current path, and the channel layer 35 becomes a resistor layer of the resistor element 100. In addition, the channel layer 35 has a sheet resistance several times as high (for example, 400 Ω/□) as that of the cap layer 37. Thus, the resistor element 100 having a high resistance value is realized with a short distance.

Therefore, despite the high resistance value, an area occupied by the resistor element 100 on the chip can be reduced. Thus, miniaturization of the chip is realized.

As shown in FIG. 3B, the operation region 12 of a HEMT 110 that is an active element is also formed by isolating the substrate by use of the insulating region 50.

Specifically, in the HEMT, a source electrode 15 and a drain electrode 16, which are formed of the ohmic metal layer 10 of the first metal layer, are connected to a source region 37s and a drain region 37d on the operation region 12. In addition, on the source and drain electrodes 15 and 16, the source electrode 25 and the drain electrode 26 are formed, respectively, by use of the pad metal layer 30.

Moreover, in the operation region 12, a portion of the cap layer 37, in which the gate electrodes 17 are disposed, is removed by etching, and the undoped AlGaAs layer 36 is exposed. Thereafter, the gate metal layer 20 of the second metal layer is contacted with the AlGaAs layer 36 to form Schottky junction, and the gate electrodes 17 are formed.

Moreover, although not shown in FIGS. 3A and 3B here, peripheral impurity regions are also formed to have a predetermined shape by being isolated by the insulating region 50.

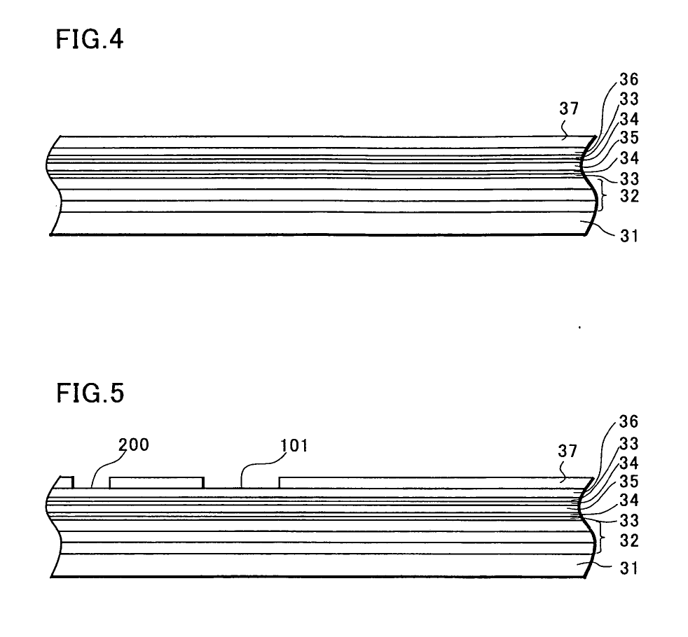

With reference to FIGS. 4 to 11, description will be given of a method of manufacturing a semiconductor device according to the first embodiment of the present invention. Note that, in the following drawings, an alignment mark 200 and formation regions of a resistor element 100 and a HEMT 110 will be shown in one cross section.

The method of manufacturing a semiconductor device according to the first embodiment of the present invention is a method of manufacturing a semiconductor device in which semiconductor layers to be a buffer layer, electron supply layers, a channel layer, a barrier layer and a cap layer are grown on a semiconductor substrate, and active elements and resistor elements are monolithically integrated. The method includes the steps of: forming an alignment mark and a recessed part having a predetermined pattern of the resistor element, in which the semiconductor layer below the cap layer is exposed, by etching the cap layer; and forming resistor element electrodes which are connected, respectively, to the cap layer left at both ends of the recessed part.

First step (FIG. 4): first, epitaxial layers to be a buffer layer, electron supply layers, a channel layer, a barrier layer, and a cap layer are grown on a semiconductor substrate.

Specifically, an undoped buffer layer 32 is grown on a semi-insulating GaAs substrate 31. The buffer layer 32 is a high-resistance layer having no impurities doped therein, which has a thickness of about several thousand A and is often formed by use of a plurality of layers.

On the buffer layer 32, an n+ type AlGaAs layer 33 to be an electron supply layer, a spacer layer 34, an undoped InGaAs layer 35 to be a channel layer, the spacer layer 34, and the n+ type AlGaAs layer 33 to be an electron supply layer are sequentially grown. In the electron supply layers 33, about 2 to 4×10¹⁸ cm⁻³ of n-type impurities (for example, Si) are doped.

In order to secure a predetermined breakdown voltage and a pinch-off voltage, an undoped AlGaAs layer to be a barrier layer 36 is grown on the electron supply layer 33. Moreover, an n+ type GaAs layer 37 to be a cap layer is grown as an uppermost layer.

Second step (FIG. 5): Next, an alignment mark and a recessed part of a resistor element are formed.

Specifically, a resist (not shown) is formed on the entire surface of the resultant structure. Thereafter, a photolithography process is performed to selectively form openings of an alignment mark 200 for aligning a mask and a recessed part 101 in a region where a register element 100 is formed. Subsequently, the cap layer 37 is removed by etching. Thus, the alignment mark 200 and the recessed part 101 of the resistor element 100 having the barrier layer 36 exposed in its bottom, respectively, are formed. Thereafter, the resist is removed.

In this event, the n+ type GaAs layer 37 and the AlGaAs layer 36 can be selectively etched by dry etching using predetermined gas. Thus, the recessed part 101 having a good reproductivity can be formed. The recessed part 101 is formed by etching the cap layer 37, for example, by a length of about 50 μm so as to have a predetermined resistance value (for example, 10 KΩ) based on a sheet resistance (for example, about 400 Ω/□) of the channel layer 35.

Incidentally, epitaxial structures of HEMTs are not limited to the aforementioned ones. The present invention can also be similarly carried out in the case of an epitaxial structure in which an undoped AlGaAs layer 36 and an n+ type GaAs layer 37 are further repeatedly provided between the cap layer 37 and the barrier layer 36.

In such a case, selective etching by dry etching is similarly repeated. In this event, a bottom of the recessed part 101 may not be the barrier layer 36.

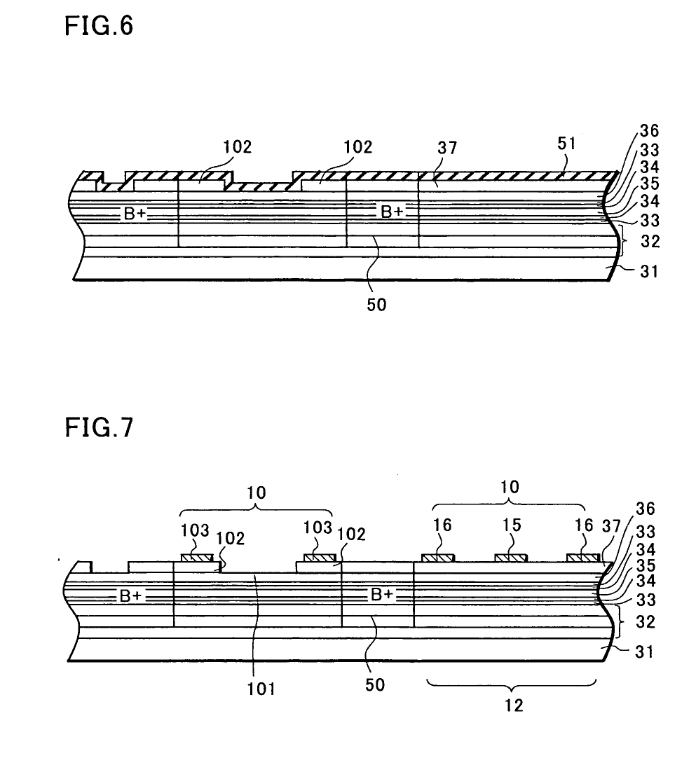

Third step (FIG. 6): After a insulating film 51 (a nitride film, for example) is deposited on the entire surface of the resultant structure, a resist (not shown) is formed thereon, and a photolithography process is performed to selectively form an opening of a portion to be an insulating region. In this event, a mask having a predetermined pattern formed thereon is used so as to form an opening corresponding to the entire region except for impurity regions required for a switch circuit device. By aligning this mask with the alignment mark, photolithography is performed. Thereafter, by use of the resist developed into a predetermined pattern as a mask, ions of B+ are implanted through the insulating film 51. Subsequently, the resist is removed, and annealing is performed for about 30 seconds at 500° C. to form an insulating region 50 which reaches the buffer layer 32. The insulating region 50 does not have complete electrical insulation characteristics, but is a region insulated by providing a carrier trap in the epitaxial layer by ion implantation of impurities (B+). Specifically, although impurities exist also in the insulating region 50 as the epitaxial layer, the impurities are inactivated by B+injection for insulation.

Thus, the formation region of the resistor element is isolated, and the cap layer 37 at both ends of the recessed part 101 becomes contact parts 102 to which resistor element electrodes are connected. At the same time, the formation region of the HEMT and a formation region of a peripheral impurity region (not shown) are isolated.

Fourth step (FIG. 7): The insulating film 51 on the entire surface of the resultant structure is removed, a resist is formed again on the entire surface, and a photolithography process is performed to selectively form an opening of an electrode formation region for formation of ohmic electrodes. After an ohmic metal layer (AuGe/Ni/Au) 10 is evaporated on the entire surface of the resultant structure, and is lifted off, the layer is alloyed.

Thus, resistor element electrodes 103 of a first metal layer formed of the ohmic metal layer are formed on the contact parts 102 of the resistor element 100. At the same time, a source electrode 15 and drain electrodes 16 of the first metal layer 10 are formed, which are connected to a part of an operation region 12 of the HEMT.

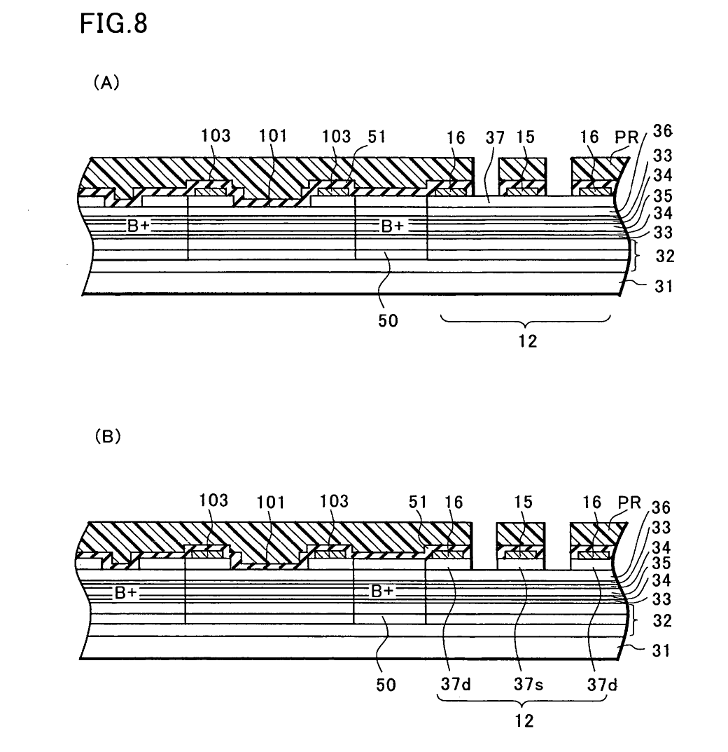

Fifth step (FIGS. 8A and 8B): A insulating film 51 is deposited again on the entire surface of the resultant structure, and a new resist is provided for forming gate electrodes. Thereafter, a photolithography process is performed to selectively form openings in portions of the resist corresponding to the gate electrodes. Subsequently, the insulating film 51 exposed in the openings are removed (FIG. 8A).

Thereafter, the cap layer 37 exposed in the openings is further removed by dry etching, and the barrier layer 36 is exposed in a gate electrode formation region. Although not shown in detail, the cap layer 37 is side-etched so as to be 0.2 μm away from gate electrodes to be formed later. The etching of the cap layer 37 in the portions of the gate electrodes simultaneously leads to formation of a source region 37s and drain regions 37d (FIG. 8B). Specifically, the source region 37s and the drain regions 37d are automatically formed during formation of the gate electrodes.

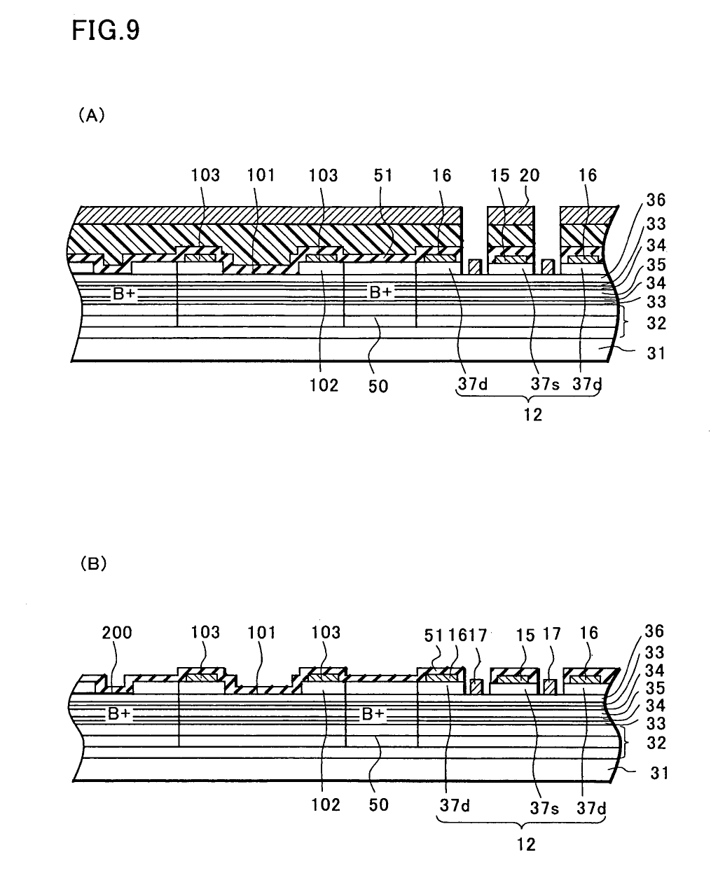

Sixth step (FIGS. 9A and 9B): A gate metal layer 20 is evaporated on the entire surface of the resultant structure. The gate metal layer 20 is formed, for example, by evaporating Ti/Pt/Au in the case of Ti gate electrodes, and is formed by evaporating Pt/Mo in the case of Pt-buried gate electrodes (FIG. 9A).

Thereafter, lift-off is performed to form gate electrodes 17 which form Schottky junctions with the barrier layer 36 (FIG. 9B). Moreover, although not shown, heat treatment is performed after the lift-off in the case of the Pt-buried gate electrodes, and the gate electrodes which are partially buried in the barrier layer 36 are formed. Note that a gate wiring 27 by which the gate electrodes 17 are bundled is also formed in this step.

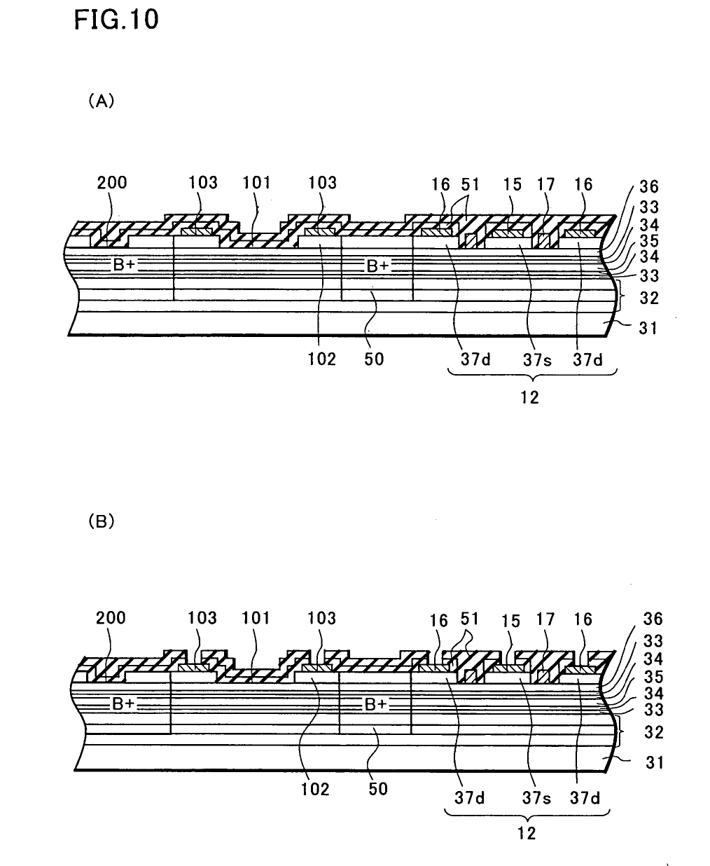

Seventh step (FIGS. 10A and 10B): A insulating film 51 to be a passivation film is formed again on the entire surface of the resultant structure (FIG. 10A). Thereafter, a new resist (not shown) is provided for forming contact holes, and photo-etching is performed. Thus, the insulating film 51 is etched, and the contact holes are formed on the resistor element electrodes 103, the source electrode 15, and the drain electrodes 16, all of which are formed of the first metal layer (FIG. 10B).

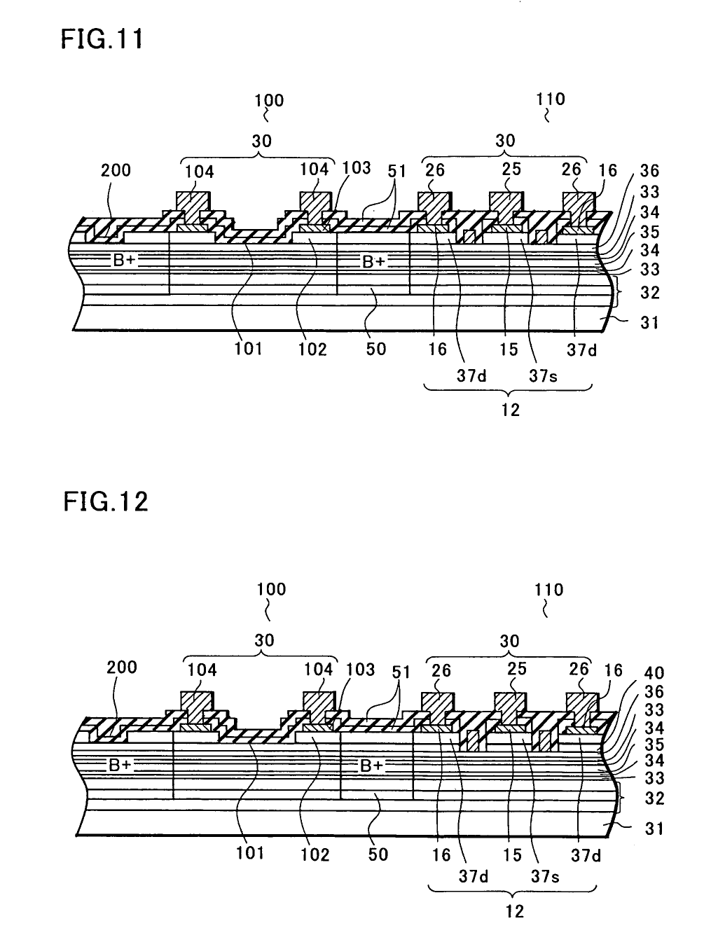

Eighth step (FIG. 11): Electrodes, which are formed of a third metal layer, are formed. Specifically, a new resist (not shown) is provided, and a photolithography process is performed to selectively form openings of electrode formation regions. Thereafter, a pad metal layer (Ti/Pt/Au) 30 is evaporated and lifted-off.

Thus, resistor element electrodes 104 of the third metal layer are formed in the resistor element region, and formation of the resistor element 100 is completed. Moreover, a source electrode 25 and drain electrodes 26 of the third metal layer are formed in the operation region 12, and the HEMT 110 is simultaneously formed.

Moreover, although not shown, respective pad electrodes and a wiring 22 having a desired pattern are also formed.

As described above, in this embodiment, the resistor element 100 having the recessed part 101 in which the barrier layer 36 is exposed, and the HEMT 110 can be monolithically integrated. Since a part of the cap layer 37 is removed by the recessed part 101, a resistor layer of the resistor element 100 becomes the channel layer 35. The channel layer 35 has a sheet resistance higher than that of the cap layer 37. Thus, a high resistance value can be obtained by use of a short pattern.

Moreover, the recessed part 101 is formed in the same step as that of forming the alignment mark 200 for aligning a mask. Furthermore, the resistor element electrodes 103 and 104 can be formed in the same steps as those of forming the source electrode 15 and the drain electrode 16 and the source electrode 25 and the drain electrode 26 in the HEMT, respectively. Therefore, without adding a special step, the resistor element 100 having a high resistance value and a reduced occupation area can be formed.

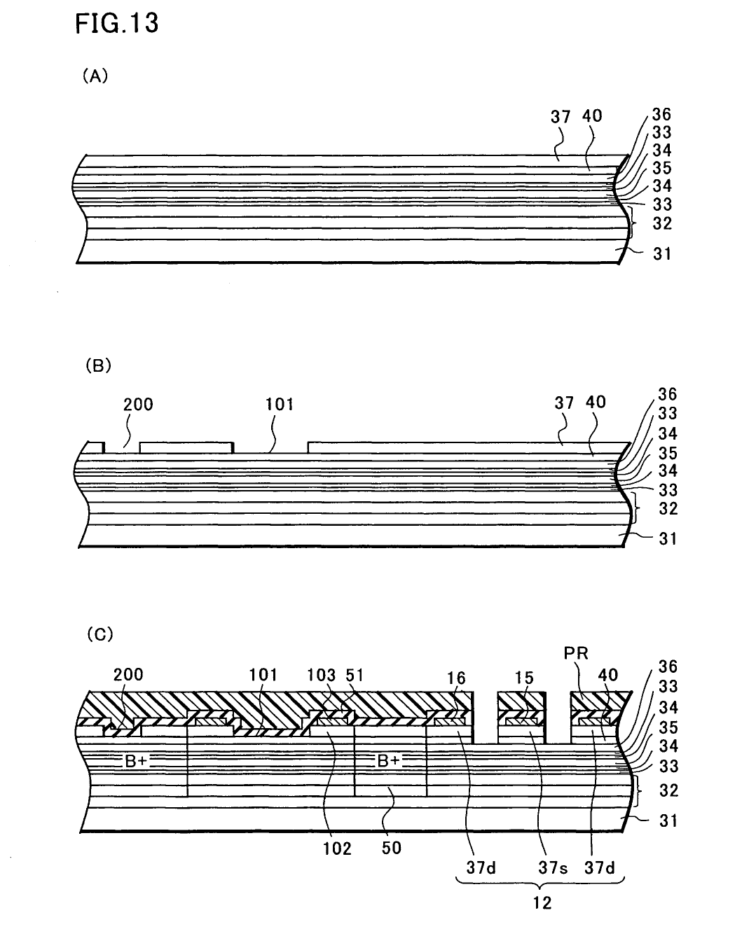

FIGS. 12, 13A, 13B and 13C show a second embodiment of the present invention. The second embodiment has a structure in which an InGaP layer 40 is provided on a barrier layer 36 in the first embodiment, and the InGaP layer 40 is exposed in the bottom of a recessed part 101 of a resistor element 100.

Accordingly, the AlGaAs barrier layer 36, which is easily oxidized, is covered with the InGaP layer 40 having a stable surface condition. Thus, a resistor element 100 having a better reliability than that of the first embodiment can be obtained.

Moreover, in formation of the recessed part 101, a GaAs cap layer 37 can be easily subjected to selective etching with a very large selection ratio to the InGaP layer by wet etching. Therefore, the recessed part 101 having a good reproductivity can be formed at low cost.

With reference to FIGS. 13A to 13C, a manufacturing method of the second embodiment will be described. Note that description overlapped with that of the first embodiment will be omitted.

First step (FIG. 13A): an undoped buffer layer 32 is grown on a semi-insulating GaAs substrate 31. The buffer layer 32 is a high-resistance layer having no impurities doped therein, which has a thickness of about several thousand A and is often formed by use of a plurality of layers.

On the buffer layer 32, an n+ type AlGaAs layer 33 to be an electron supply layer, a spacer layer 34, an undoped InGaAs layer 35 to be a channel layer, another spacer layer 34, and an n+ type AlGaAs layer 33 to be another electron supply layer are sequentially grown. In the electron supply layers 33, about 2 to 4×10¹⁸ cm⁻³ of n-type impurities (for example, Si) are doped.

In order to secure a predetermined breakdown voltage and a pinch-off voltage, an undoped AlGaAs layer to be a barrier layer 36 is grown on the electron supply layer 33. Thereafter, an n+ type InGaP layer 40 to be a passivation layer and an etching stop layer is grown thereon. An impurity concentration of the InGaP layer 40 is about 2 to 3×10¹⁸ cm⁻³. Subsequently, an n+ type GaAs layer 37 to be a cap layer is grown as an uppermost layer.

Second step (FIG. 13B): Next, an alignment mark and a recessed part of a resistor element are formed.

Specifically, a resist (not shown) is formed on the entire surface of the resultant structure, and a photolithography process is performed to selectively form openings of formation regions of an alignment mark 200 and a recessed part 101 of a resistor element 100. Subsequently, the cap layer 37 exposed in the openings is removed by etching. Thus, the alignment mark 200 and the recessed part 101 are formed.

A large selection ratio for wet etching can be set between the n+ type GaAs layer 37 and the n+ type InGaP layer 40, and the InGaP layer 40 becomes the etching stop layer. Therefore, the recessed part 101 having a good reproductivity can be formed by wet etching. Thus, the second embodiment has an advantage that the recessed part 101 can be formed at a lower cost than the case of the first embodiment in which the recessed part 101 is formed by dry etching.

In addition to the channel layer 35, the n+ type InGaP layer 40 also becomes somewhat of a current path of the resistor element 100. The cap layer 37 is etched to form the recessed part 101 having a desired resistance value based on a sheet resistance of a resistor layer obtained by combining the two layers described above. Thereafter, the resist is removed.

Third and fourth steps: By the steps similar to those of the first embodiment, resistor element electrodes 103 of a first metal layer, and a source electrode 15 and drain electrodes 16 of a first metal layer are formed.

Fifth step (FIG. 13C): A insulating film 51 is deposited on the entire surface of the resultant structure, and a new resist is provided for formation of gate electrodes. Thereafter, a photolithography process is performed to selectively form openings in the resist in portions of the gate electrodes, and the insulating film 51 exposed in the openings of the resist is removed. Subsequently, the cap layer 37 is wet-etched by use of phosphoric acid and the like.

Next, the n+ type InGaP layer 40 exposed in the openings is etched by use of a hydrochloric-acid-based etchant. Accordingly, the barrier layer 36 is exposed in gate electrode formation regions.

Thereafter, by sixth to eighth steps similar to those of the first embodiment, after gate electrodes 17 are formed by use of a gate metal layer 20, resistor element electrodes 104 are formed by use of a pad metal layer 30. At the same time, a second source electrode 25 and second drain electrodes 26 of a HEMT are formed. Thus, the final structure shown in FIG. 12 is obtained.

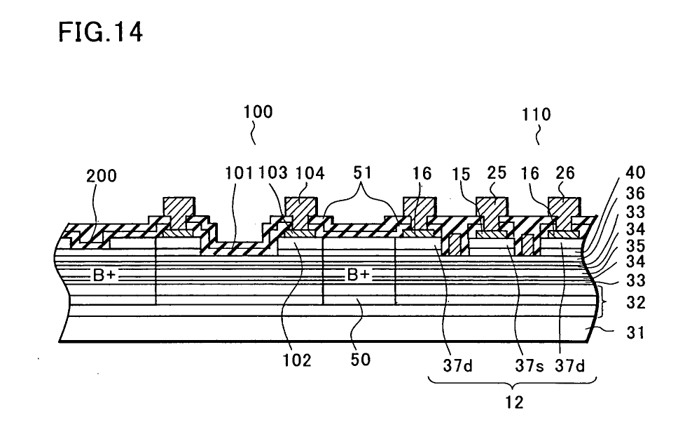

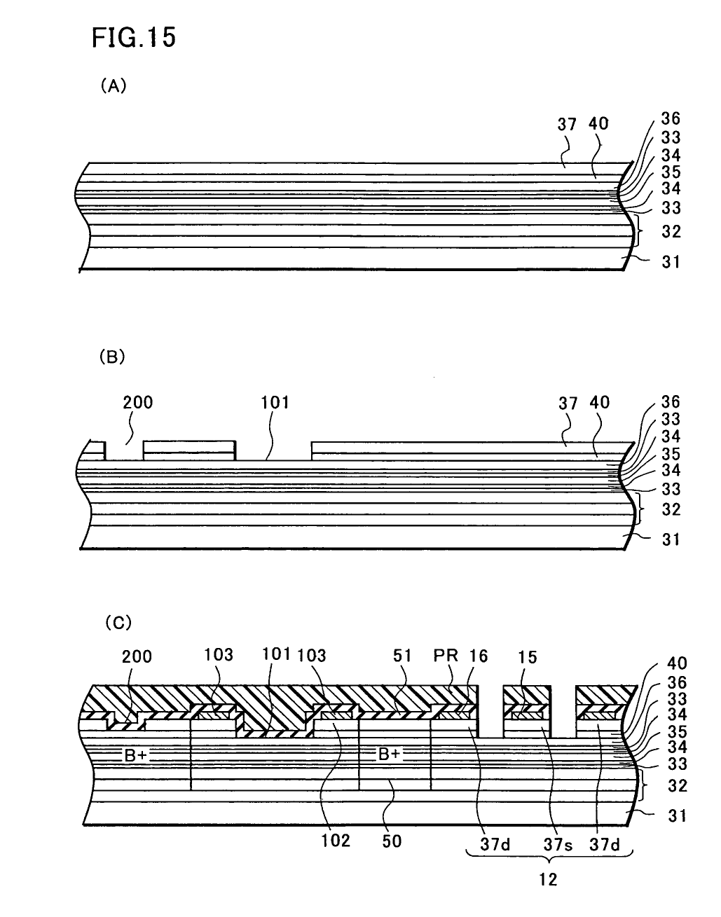

FIGS. 14, 15A, 15B and 15C show a third embodiment of the present invention.

As shown in FIG. 14, the third embodiment has a structure in which an InGaP layer 40 is provided on a barrier layer 36 in the first embodiment, and the barrier layer 36 is exposed in the bottom of a recessed part 101 of a resistor element 100. In the second embodiment in which the InGaP layer 40 is similarly provided, since the high-concentration InGaP layer 40 also becomes the resistor layer, in addition to a channel layer 35, the sheet resistance is slightly lowered compared with the case of the first embodiment. However, in the third embodiment, since the high-concentration InGaP layer 40 is also removed in the recessed part 101, only the channel layer 35 can become the resistor layer as in the case of the first embodiment. Therefore, the sheet resistance can be set the same as that of the first embodiment, the sheet resistance value can be increased compared with the case of the second embodiment, and the resistance value can be increased with the same length.

With reference to FIGS. 15A to 15C, a manufacturing method of the third embodiment will be described. Note that description overlapped with that of the first embodiment will be omitted.

First step (FIG. 15A): an undoped buffer layer 32 is grown on a semi-insulating GaAs substrate 31. The buffer layer 32 is a high-resistance layer having no impurities doped therein, which has a thickness of about several thousand A and is often formed by use of a plurality of layers.

On the buffer layer 32, an n+ type AlGaAs layer 33 to be an electron supply layer, a spacer layer 34, an undoped InGaAs layer 35 to be a channel layer, another spacer layer 34, and an the n+ type AlGaAs layer 33 to be another electron supply layer are sequentially grown. In the electron supply layers 33, about 2 to 4×10¹⁸ cm⁻³ of n-type impurities (for example, Si) are doped.

In order to secure a predetermined breakdown voltage and a pinch-off voltage, an undoped AlGaAs layer to be a barrier layer 36 is grown on the electron supply layer 33. Thereafter, an n+ type InGaP layer 40 to be a passivation layer and an etching stop layer is grown thereon. An impurity concentration of the InGaP layer 40 is about 2 to 3×10¹⁸ cm⁻³. Subsequently, an n+ type GaAs layer 37 to be a cap layer is grown as an uppermost layer.

Second step (FIG. 15B): Next, an alignment mark and a recessed part of a resistor element are formed.

Specifically, a resist (not shown) is formed on the entire surface of the resultant structure, and a photolithography process is performed to selectively form openings of formation regions of the alignment mark and the recessed part. Thereafter, the cap layer 37 exposed in the openings is removed by use of an etchant such as phosphoric acid.

Subsequently, the n+ type InGaP layer 40 exposed in the openings is removed by use of a hydrochloric-acid-based etchant, and an alignment mark 200 and a recessed part 101, in which the barrier layer 36 is exposed, are formed.

In wet etching, an etching selection ratio between the n+ type GaAs layer 37 and the n+ type InGaP layer 40 is large, and an etching selection ratio between the InGaP layer 40 and the AlGaAs layer 36 that is the barrier layer is also large. Therefore, by changing the etchant, the recessed part 101 having a good reproductivity can be formed by wet etching. Thus, the third embodiment has an advantage that the recessed part 101 can be formed at a lower cost than the case of the first embodiment in which the recessed part is formed by dry etching.

The cap layer 37 and the InGaP layer 40 are etched to form the recessed part 101 having a predetermined resistance value based on a sheet resistance of the channel layer 35. Thereafter, the resist is removed.

Third and fourth steps: By the steps similar to those of the first embodiment, resistor element electrodes 103 of a first metal layer, and a source electrode 15 and drain electrodes 16 of a first metal layer are formed.

Fifth step (FIG. 15C): A insulating film 51 is deposited on the entire surface of the resultant structure, and a new resist is provided for formation of gate electrodes. Thereafter, a photolithography process is performed to selectively form openings in the resist in portions of the gate electrodes, and the cap layer 37 exposed in the openings of the resist is wet-etched by use of phosphoric acid and the like. Subsequently, the n+ type InGaP layer 40 is etched by use of a hydrochloric-acid-based etchant, and the barrier layer 36 is exposed in gate electrode formation regions.

Thereafter, by sixth to eighth steps similar to those of the first embodiment, after gate electrodes 17 are formed by use of a gate metal layer 20, resistor element electrodes 104 are formed by use of a pad metal layer 30. At the same time, a second source electrode 25 and second drain electrodes 26 of a HEMT are formed. Thus, the final structure shown in FIG. 14 is obtained.

As described in detail above, the following effects can be obtained according to the embodiments of the present invention.

First, the cap layer is removed in a predetermined pattern, and the recessed part is provided, in which the semiconductor layer below the cap layer is exposed. Thereafter, the resistor element electrodes are provided on the cap layer at the both ends of the recessed part. Thus, it is possible to realize a resistor element which includes a channel layer having a high sheet resistance as a resistor layer without including the cap layer. Moreover, since the cap layer is left in portions of the resistor element electrodes, a low contact resistance value can be maintained.

Second, since the channel layer has a sheet resistance several times as high as that of the cap layer, the same resistance value can be obtained with a shorter distance than the case where the resistor layer includes the cap layer. Therefore, a distance for which a resistor is extended within a chip can be reduced to one part in several, and an increase in a chip area can be suppressed in the case where a resistor having high resistance is connected.

Third, by providing the InGaP layer on the barrier layer, the InGaP layer can be used as an etching stop layer. Thus, stability of a process can be enhanced.

Fourth, the InGaP layer is provided on the barrier layer, and the InGaP layer having a stable surface is exposed in a bottom of the recessed part. Thus, it is possible to surely protect the channel layer therebelow, and to increase reliability.

Fifth, by removing the cap layer so as to expose the barrier layer in the bottom of the recessed part, it is possible to surely set only the channel layer to be the resistor layer.

Moreover, if the InGaP layer used as the etching stop layer on the barrier layer is doped with impurities, this InGaP layer is also removed, and the bottom of the recessed part is set to be the barrier layer. Thus, the sheet resistance of the resistor element can be further increased.

Sixth, the electron supply layer, the channel layer, the barrier layer, and the cap layer are the n+ type AlGaAs layer, the undoped InGaAs layer, the undoped AlGaAs layer, and the n+ type GaAs layer, respectively. Thus, a substrate structure suitable for a switch circuit device is realized. Specifically, in a switch circuit device using a HEMT having good characteristics, a resistor element having a high sheet resistance and a small occupation area can be monolithically integrated.

Seventh, according to the manufacturing method of the embodiment of the present invention, the recessed part of the resistor element is formed simultaneously with formation of the alignment mark, and the resistor element electrodes can be formed simultaneously with formation of the electrodes of the HEMT. Therefore, without adding a special step, the HEMT and the resistor element having a high sheet resistance and a small occupation area can be monolithically integrated.

Eighth, since the barrier layer is the AlGaAs layer, and the cap layer is the n+ type GaAs layer, those layers can be selectively etched by dry etching using predetermined gas, and the recessed part can be formed with a good reproductivity.

Ninth, by providing the InGaP layer on the barrier layer, selective etching by wet etching can be performed. Therefore, the recessed part can be formed with a good reproductivity at low cost without using an expensive dry etching apparatus.

Moreover, the barrier layer, which is easily oxidized, can be protected by the InGaP layer having a stable surface, and the reliability can be increased.

The recessed part having the barrier layer exposed therein may be formed by changing an etchant and further selectively etching the InGaP layer. Even in this case, the recessed part can be formed with a good reproducibility.

1. A semiconductor device comprising:
a semiconductor substrate;
a multi-layer stack formed on the semiconductor substrate, the stack comprising a buffer layer formed on the semiconductor substrate, a first electron supply layer formed on the buffer layer, a channel layer formed on the first electron supply layer, a second electron supply layer formed on the channel layer, a barrier layer formed on the second electron supply layer, and a cap layer formed on the barrier layer;
an active device element formed on the stack; and
a resistor element connected with the active device element, the resistor element comprising a first resister element electrode and a second resistor element electrode that are formed on the cap layer,
wherein the cap layer is removed along a path between the first and second resistor element electrodes.

2. The semiconductor device of claim 1, wherein a sheet resistance of the channel layer is higher than a sheet resistance of the cap layer.

3. The semiconductor device of claim 1, further comprising an insulating film that is in contact with the barrier layer along the path between the first and second resistor element electrodes.

4. The semiconductor device of claim 1, wherein the multi-layer stack further comprises an InGaP layer disposed between the barrier layer and the cap layer.

5. The semiconductor device of claim 4, further comprising an insulating film that is in contact with the InGaP layer along the path between the first and second resistor element electrodes.

6. The semiconductor device of claim 1, wherein each of the first and second electron supply layers comprises an impurity-doped AlGaAs layer, the channel layer comprises an undoped InGaAs layer, the barrier layer comprises an undoped AlGaAs layer, and the cap layer comprises an impurity-doped GaAs layer.

7. The semiconductor device of claim 1, wherein the active device element comprises a transistor comprising a source electrode and a drain electrode that are in contact with the cap layer and a gate electrode that is in contact with the barrier layer.

8. A method of manufacturing a semiconductor device, comprising:
providing a semiconductor substrate having a multi-layer stack formed thereon, the stack comprising a buffer layer formed on the semiconductor substrate, a first electron supply layer formed on the buffer layer, a channel layer formed on the first electron supply layer, a second electron supply layer formed on the channel layer, a barrier layer formed on the second electron supply layer, and a cap layer formed on the barrier layer;
removing a first portion of the cap layer to form a recess;
forming a first resistor element electrode on the cap layer and adjacent one end of the recess;
forming a second resister element electrode on the cap layer and adjacent other end of the recess; and
filling the recess with an insulating film.

9. The method of claim 8, further comprising removing a second portion of the cap layer to form an alignment mark when the first portion of the cap layer is removed.

10. The method of claim 8, wherein the removing of the first portion of the cap layer is performed by a dry etching.

11. The method of claim 8, wherein the multi-layer stack further comprises an InGaP layer disposed between the barrier layer and the cap layer, and the removing of the first portion of the cap layer exposes the InGaP layer.

12. The method of claim 8, wherein each of the first and second electron supply layers comprises an impurity-doped AlGaAs layer, the channel layer comprises an undoped InGaAs layer, the barrier layer comprises an undoped AlGaAs layer, and the cap layer comprises an impurity-doped GaAs layer.

13. The method of claim 8, further comprising forming a source electrode and a drain electrode on the cap layer, removing a third portion of the cap layer between the source and drain electrodes, and forming a gate electrode between the source and drain electrodes that is in contact with the burrier layer.

14. The method of claim 13, wherein the first and second resistor element electrodes are formed when the source and drain electrodes are formed.

15. A semiconductor device comprising:
a semiconductor substrate;
a multi-layer stack formed on the semiconductor substrate, the stack comprising a buffer layer formed on the semiconductor substrate, an electron supply layer formed on the buffer layer, a channel layer formed on the electron supply layer, a barrier layer formed on the channel layer, and a cap layer formed on the barrier layer;
an active device element formed on the stack; and
a resistor element connected with the active device element, the resistor element comprising a first resister element electrode and a second resistor element electrode that are formed on the cap layer,
wherein the cap layer is removed along a path between the first and second resistor element electrodes.

16. A semiconductor device comprising:
a semiconductor substrate;
a multi-layer stack formed on the semiconductor substrate, the stack comprising a buffer layer formed on the semiconductor substrate, a channel layer formed on the buffer layer, an electron supply layer formed on the channel layer, a barrier layer formed on the electron supply layer, and a cap layer formed on the barrier layer;
an active device element formed on the stack; and
a resistor element connected with the active device element, the resistor element comprising a first resister element electrode and a second resistor element electrode that are formed on the cap layer,
wherein the cap layer is removed along a path between the first and second resistor element electrodes.
